(19) United States
(12) Patent Application Publication
(10) Pub. No.: US 2023/0207593 A1
(43) Pub. Date: Jun. 29, 2023

(54) MULTILAYER SUBSTRATE AND IMAGE SENSOR UNIT

(71) Applicant: CANON KABUSHIKI KAISHA, Tokyo (JP)

(72) Inventor: Daisuke TODA, Kanagawa (JP)

(21) Appl. No.: 18/170,639

(22) Filed: Feb. 17, 2023

Related U.S. Application Data
(63) Continuation of application No. PCT/JP21/29834, filed on Aug. 13, 2021.

(30) Foreign Application Priority Data
Aug. 25, 2020 (JP) 2020-141794

(51) Int. Cl. H01L 27/146

(52) U.S. Cl. CPC H01L 27/14623; H01L 27/14636

(57) ABSTRACT

A multilayer substrate on which an image sensor is mounted and which includes a plurality of conductive layers includes a plurality of vias (a drill via and a small-diameter via) piled and connected in a straight line; and a light-shielding portion configured to shield light transmitted through a non-wired region insulating the vias and other wirings and traveling to the image sensor. The light-shielding portion is a land of the via formed in a range broader than the non-wired region of another conductive layer in at least one conductive layer.

### CROSS-REFERENCE TO RELATED APPLICATIONS

This application is a Continuation of International Patent Application No. PCT/JP2021/029834, filed Aug. 13, 2021, which claims the benefit of Japanese Patent Application No. 2020-141794 filed Aug. 25, 2020, both of which are hereby incorporated by reference herein in their entirety.

### BACKGROUND OF THE INVENTION

### Field of the Invention

The present invention relates to a multilayer substrate and an image sensor unit.

### Background Art

In the related art, as a configurations of packaging of an image sensor unit, an image sensor is generally mounted in a package formed of a ceramic with a cavity structure in a recessed state. In recent years, since miniaturization and weight reduction have become preferable, structures known as packageless structures in which image sensors are directly mounted on substrates have been proposed. Patent Literature 1 discloses an example in which an imaging chip is mounted on a substrate by a chip-on board (COB) mounting.

### CITATION LIST

Patent Literature

Patent Literature 1 Japanese Patent Laid-Open No. 2015-012211

In a packageless structure, however, light may be transmitted in a space where there is no conductor to insulate signal wirings of a substrate (hereinafter referred to as a non-wired region), and thus light from the rear surface of an image sensor which is a substrate side may also be imaged. As sensitivity of image sensors advances, it is becoming highly necessary to shield light from the rear surface of an image sensor. However, when a light-shielding member is added to an image sensor unit with a packageless structure or an imaging device on which an image sensor unit with a packageless structure is mounted in order to shield light from the rear surface of an image sensor, cost may increase.

### SUMMARY OF THE INVENTION

An object of the present invention is to shield light which is transmitted through a substrate on which an image sensor is mounted and is incident on the image sensor.

To solve the foregoing problem, according to an aspect of the present invention, a multilayer substrate on which an image sensor is mounted and which includes a plurality of conductive layers includes: a plurality of vias piled and connected in a straight line; and a light-shielding portion configured to shield light transmitted through a non-wired region insulating the vias and other wirings and traveling to the image sensor.

According to the present invention, it is possible to shield light which is transmitted through a substrate on which an image sensor is mounted and is incident on the image sensor.

Further features of the present invention will become apparent from the following description of exemplary embodiments with reference to the attached drawings.

### BRIEF DESCRIPTION OF THE DRAWINGS

FIG. 1 is a diagram illustrating an imaging device including an image sensor unit.

FIG. 2 is a diagram illustrating a configuration of the image sensor unit.

FIGS. 3A and 3B are diagrams illustrating an overview of a layout of a multilayer substrate.

FIG. 4 is a diagram illustrating a structure of a multilayer substrate of the related art.

FIGS. 5A to 5G are diagrams illustrating disposition of a wiring and a via of each conductive layer of the multilayer substrate of the related art.

FIGS. 6A to 6G are diagrams illustrating disposition of a wiring and a via of each conductive layer of the multilayer substrate according to an embodiment.

FIG. 7 is a diagram illustrating a structure of a multilayer substrate according to the embodiment.

### DESCRIPTION OF THE EMBODIMENTS

### First Embodiment

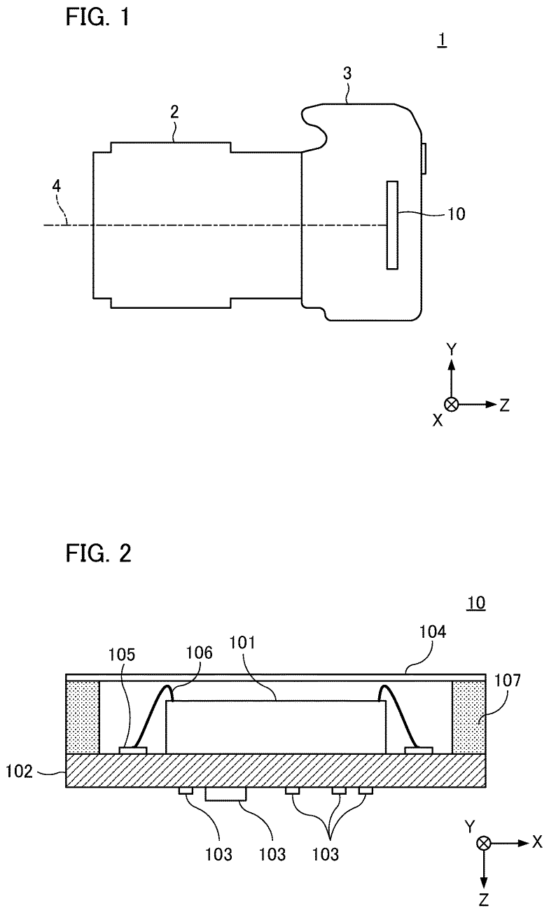

FIG. 1 is a diagram illustrating an imaging device including an image sensor unit according to an embodiment. An imaging device 1 is, for example, an imaging device such as a digital single-lens reflex camera, a video camera, or a compact digital camera. The imaging device 1 includes a lens unit 2 and a camera body 3. The imaging device 1 may be an imaging device in which the lens unit 2 and the camera body 3 are integrated or may be a detachable-lens imaging device in which the lens unit 2 can be detachably mounted on the camera body 3. The imaging device 1 may be mirrorless camera.

The camera body 3 includes an image sensor unit 10. The details of the image sensor unit 10 will be described below with reference to FIG. 2. An optical axis 4 is an optical axis of an imaging optical system of the imaging device 1. In the imaging device 1, the optical axis 4 is referred to as the Z axis and a direction oriented from a subject (not illustrated) to the imaging device 1 is referred to as a positive direction of the Z axis. A perpendicular direction at a regular position of the imaging device 1 is referred to as the Y axis and a direction oriented upward is referred to as a positive direction. A direction orthogonal to the Y and Z axes is referred to as the X axis.

FIG. 2 is a diagram illustrating a configuration of the image sensor unit according to the embodiment. The image sensor unit 10 includes an image sensor 101, a multilayer substrate 102, components 103, a cover glass 104, a wire-bonding pad 105, a connection conductor 106, and a frame 107. The image sensor 101 outputs an image signal in accordance with incident light. The image sensor 101 is, for example, an image sensor in which a complementary metal oxide semiconductor (CMOS) is used. The image sensor 101 includes a photoelectric conversion portion and outputs an electric signal in accordance with light.

The image sensor 101 is mounted on the multilayer substrate 102. A surface of the image sensor 101 in the +Z direction is bonded to a surface of the multilayer substrate 102 in the −Z direction using, for example, an adhesive. The components 103 are disposed on the surface of the multilayer substrate 102 in the +Z direction. Hereinafter, a surface of the multilayer substrate 102 in the −Z direction on which the image sensor 101 is mounted is referred to as an upper surface of the multilayer substrate 102 and a surface of the multilayer substrate 102 in the +Z direction on which the components 103 are disposed is referred to as a lower surface of the multilayer substrate 102. The multilayer substrate 102 is a printed substrate. In the multilayer substrate 102, a pattern connected to the components 103 is formed of, for example, a metal such as copper.

As the multilayer substrate 102, a rigid substrate is preferable in order to mount the image sensor 101 and is generated with glass epoxy or the like. The multilayer substrate 102 according to the present invention is not limited to the rigid substrate and may be a flexible substrate formed of a plastic material. A low-temperature simultaneous calcination ceramics (LTCC) substrate or the like in which ceramics and a copper wiring are used may be used. The multilayer substrate 102 may be substrate in which a pattern is formed with a metal wiring such as copper using a specific material and components are mounted.

The components 103 are various components disposed on the surface of the multilayer substrate 102 opposite to the image sensor 101, that is, the surface of the multilayer substrate 102 in the +Z direction. The components 103 are, for example, passive components such as capacitor, a resistance, and a coil necessary to operate the image sensor 101 or a linear regulator generating a voltage for operating the image sensor 101, an oscillator giving a clock, and the like. The components 103 may be a thermometer monitoring a state or the like of the image sensor 101 and components, such as a ROM storing solid information of the image sensor 101, for purposes other than a purpose for operating the image sensor 101. The components 103 also include a connector collectively connecting signals for exchanging power or signals between the multilayer substrate 102 and an external substrate.

The wire-bonding pad 105 is an electrode for electrically connecting the image sensor 101 to the multilayer substrate 102. The plurality of wire-bonding pads 105 are disposed around the image sensor 101. The wire-banding pads 105 are disposed on the same surface as the image sensor 101 on the multilayer substrate 102, that is, the surface of the multilayer substrate 102 in the −Z direction. The wire-bonding pads 105 are formed on a layer of the surface of the multilayer substrate 102 through, for example, gold plating.

The connection conductor 106 is a connection conductor (wire) electrically connecting the image sensor 101 to the multilayer substrate 102. One end of the connection conductor 106 is connected to the image sensor 101 and the other end of the connection conductor 106 is connected to the wire-bonding pad 105 on the multilayer substrate 102. The connection conductor 106 is a metal line and, for example, a gold line, an aluminum line, a copper line, or the like is used. The connection conductor 106 is generally connected by, for example, thermosonic bonding using a known wire-bonder, but the present invention is not limited thereto.

The cover glass 104 is a cover glass for sealing the image sensor 101. The cover glass 104 is disposed in the −Z direction from the image sensor 101. An anti-reflection coating or the like is formed on the cover glass 104. The frame 107 is a frame surrounding the image sensor 101. The frame 107 is positioned further outward than the wire-bonding pads 105. The surface of the frame 107 in the +z direction is bonded to the multilayer substrate 102 and the surface of the frame 107 in the −Z direction is bonded to the cover glass 104.

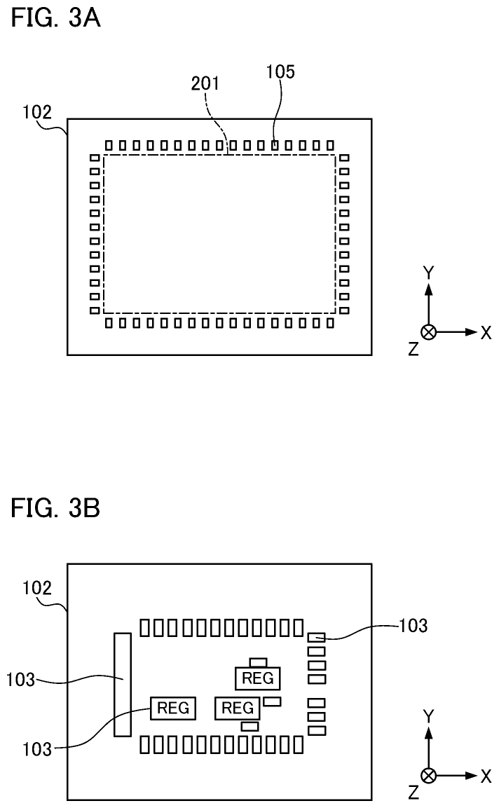

Next, a layout of the multilayer substrate 102 according to the embodiment will be described with reference to FIGS. 3A and 3B. FIGS. 3A and 3B are diagrams illustrating an overview of the layout of the multilayer substrate. FIG. 3A is a diagram illustrating the multilayer substrate 102 in the −Z direction. The image sensor 101 is mounted on the upper surface of the multilayer substrate 102. An image sensor region 201 is a region where the image sensor 101 is disposed. The longitudinal direction of the image sensor 101 is parallel to the X axis and the transverse direction of the image sensor 101 is parallel to the Y axis. The plurality of wire-bonding pads 105 are disposed around the image sensor region 201. Although not illustrated, there is a region to which the frame 107 is bonded around the wire-bonding pads 105 on the upper surface of the multilayer substrate 102.

FIG. 3B is a diagram illustrating the multilayer substrate 102 in the +Z direction. The plurality of components 103 are disposed on the lower surface of the multilayer substrate 102. The components 103 are, for example, passive components and components such as a linear regulator, a clock, an oscillator, and a connector.

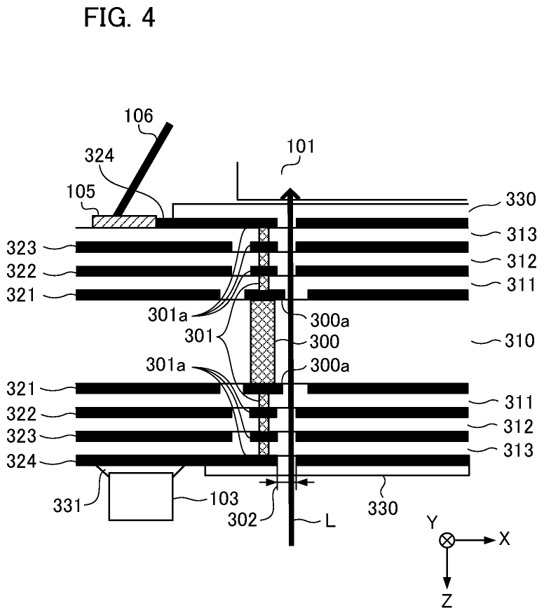

Next, the details of the multilayer substrate 102 will be described. FIG. 4 is a diagram illustrating a configuration of the multilayer substrate 102 of the related art. FIG. 4 illustrates a part of a cross-sectional diagram of the image sensor unit in FIG. 2. The multilayer substrate 102 according to the embodiment is, for example, a build-up substrate. The build-up substrate is a multilayer substrate in which build-up layers are stacked on both surfaces of a core layer.

First, the core layer will be described. The multilayer substrate 102 contains a double-sided substrate in which conductive layers 321 are provided on both surfaces of an insulation layer 310 formed of a prepreg serving as a core. The conductive layers 321 on both surfaces are connected by a drill via 300 after conductive layers 321 are patterned in a desired pattern by lithography. In the embodiment, the insulation layer 310 and the conductive layers 321 are referred to as a core layer, and the drill via 300 is referred to as an internal layer via or a core layer via.

The drill via 300 connects the conductive layers 321 on both sides of the insulation layer 310. Both ends of the drill via 300 are formed in lands 300a formed in a pattern in the conductive layers 321. The land 300a is formed in a pattern with a diameter larger than that of the drill via 300 in consideration of positional deviation of the drill via 300. In a region where insulation between the land 300a and the conductive layer 321 is necessary, a non-wired region 302 where there is no conductive layer 321 is provided. When the multilayer substrate 102 is a build-up substrate, the diameter of the drill via 300 which is a core layer via is larger than the diameter of a small-diameter via 301 which is an external layer via.

Next, the build-up layer will be described. An insulation layer 311 and a conductive layer 322 are provided in that order on each of the upper surface and the lower surface of the double-sided substrate. The conductive layer 322 is patterned in a desired pattern by lithography as in the conductive layer 321. A necessary portion of the conductive layer 322 is connected to the conductive layer 321 via the small-diameter via 301. The small-diameter via 301 is drilled by a laser or a drill. Hereinafter, the small-diameter via 301 is a front surface via or an external layer via. The small-diameter via 301 is also formed in the land 301a formed in a pattern in the conductive layer 322 as in the drill via 300. The land 301a is formed in a pattern with a diameter larger than that of the small-diameter via 301 in consideration of positional deviation of the small-diameter via 301. In a region where insulation between the land 301a and the conductive layer 322 is necessary, the non-wired region 302 where there is no conductive layer 322 is provided.

As in the insulation layer 311 and the conductive layer 322, an insulation layer 312 and a conductive layer 323, and an insulation layer 313 and a conductive layer 324 are formed. Specifically, the insulation layer 311, the conductive layer 322, the insulation layer 312, the conductive layer 323, the insulation layer 313, and the conductive layer 324 are provided in that order on each of the upper surface and the lower surface of the double-sided substrate. The drill via 300 and all the small-diameter vias 301 are piled and connected in a straight line.

The insulation layers 311, 312, and 313 are formed of a prepreg as in the insulation layer 310. The thickness of the insulation layer 310 is in the range of, for example, 0.05 to 1.5 mm, and the thicknesses of the insulation layers 311, 312, and 313 are in the range of, for example, 0.05 to 0.3 mm less than the thickness of the insulation layer 310. The prepreg is a material formed by weaving fiber in a cross form or a material formed by impregnating a resin in the woven material. The fiber is generally a glass fiber but the present invention is not limited thereto as long as the fiber has an insulation property. A resin that has epoxy or phenol as a main component is widely used. The resin contains insulation fillers such as paper or glass in many cases.

In general, copper is appropriate as conductors of the conductor layers 321, 322, 323, and 324. However, another metal may be used as necessary. In the embodiment, an example of the build-up substrate has been described as an example of the multilayer substrate 102, but the present invention is not limited to the multilayer substrate 102. For example, it may be an any-layer substrate in which an insulation layer that has a thickness similar to the thickness of the other insulation layers 311, 312, and 313 is used as the insulation layer 310. In the any-layer substrate, the small-diameter via 301 is used in all layers. That is, when the multilayer substrate 102 is an any-layer substrate, the diameter of the drill via 300 is equal to the diameter of the small-diameter via 301.

A solder resist 330 is formed on the external surface of each conductive layer 324. Here, the wire-bonding pad 105 or a position of a terminal in which the component 103 is mounted opens the solder resist 330. In the conductive layer 324 in which the solder resist 330 on the side of the image sensor 101 is opened, the wire-bonding pad 105 is formed. On the other hand, in the conductive layer 324 in which the solder resist 330 on the side of the component 103 is opened, the component 103 is connected via a solder 331. An arrow in FIG. 4 indicates a light beam L which is transmitted through the multilayer substrate 102 and is incident on the image sensor 101 from the side of the multilayer substrate 102.

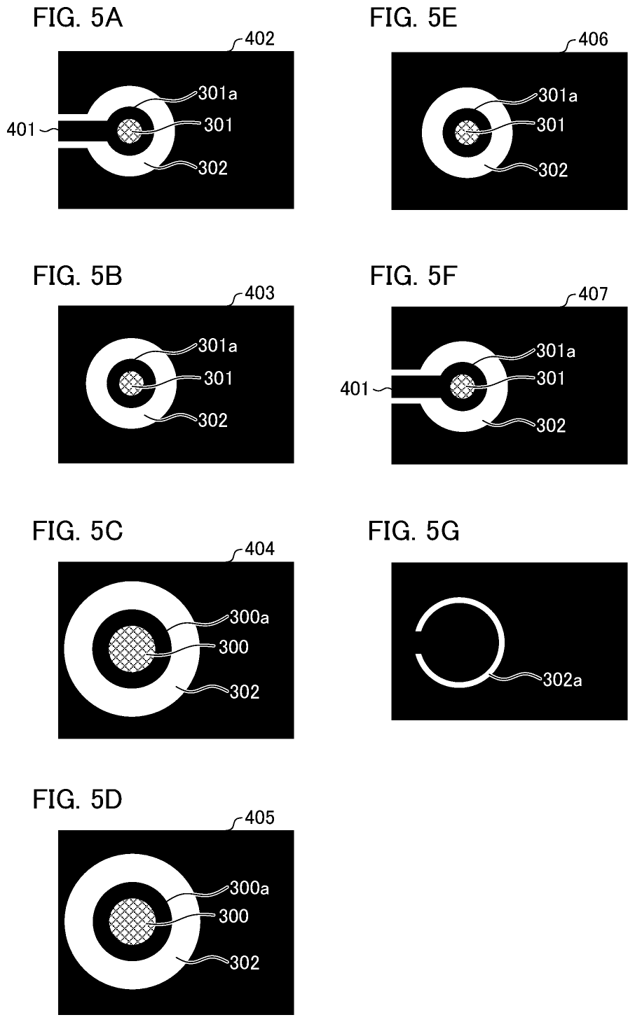

Next, disposition of each conductive layer, the drill via 300, and the small-diameter via 301 of the multilayer substrate 102 of the related art will be described with reference to FIGS. 5A to 5G. FIGS. 5A to 5G are diagrams illustrating disposition of a wiring and a via of each conductive layer of the multilayer substrate 102 of the related art.

FIG. 5A is a diagram illustrating disposition of the conductive layer 324 on the side of the image sensor 101. A wiring 401 and the land 301a are signal wirings of the conductive layer 324 connecting the small-diameter via 301 and the wire-bonding pad 105 connected to the image sensor 101. The wiring 401 is connected to the conductive layer 323 on the side of the image sensor 101, and thus is connected to the small-diameter via 301. A wiring 402 is a wiring of the conductive layer 324 on the side of the image sensor 101, which is different from the wiring 401 and the land 301a, and is a GND wiring, for example. The wiring 401 and the land 301a are insulated from the wiring 402 by the non-wired region 302 where a conductor is not wired.

FIG. 5B is a diagram illustrating disposition of conductive layers 323 and 322 on the side of the image sensor 101. The small-diameter via 301 of the conductive layer 324 illustrated in FIG. 5A is connected to the small-diameter via 301 of the conductive layer 323 illustrated in FIG. 5B. Similarly, the small-diameter via 301 of the conductive layer 323 is connected to the small-diameter via 301 of the conductive layer 322. The land 301a is a wiring of the conductive layers 322 and 323 on the side of the image sensor 101. A wiring 403 is a wiring of the conductive layers 322 and 323 on the side of the image sensor 101, which is different from the land 301a. The land 301a of the conductive layers 322 and 323 on the side of the image sensor 101 is insulated from the wiring 403 by the non-wired region 302.

FIG. 5C is a diagram illustrating disposition of the conductive layer 321 on the side of the image sensor 101. The small-diameter via 301 of the conductive layer 322 illustrated in FIG. 5B is connected to the drill via 300 of the conductive layer 321 illustrated in FIG. 5C. The small-diameter via 301 in the conductive layer 321 is connected to the drill via 300. The land 300a is a wiring of the conductive layer 321 on the side of the image sensor 101. A wiring 404 is a wiring of the conductive layer 321 on the side of the image sensor 101, which is a different form the land 300a. The land 300a of the conductive layer 321 on the side of the image sensor 101 is insulated from the wiring 404 by the non-wired region 302.

FIG. 5D is a diagram illustrating disposition of the conductive layer 321 on the side of the component 103. The small-diameter via 301 of the conductive layer 321 on the side of the image sensor 101 illustrated in FIG. 5C is connected to the drill via 300 of the conductive layer 321 on the side of the component 103 illustrated in FIG. 5D. The land 300a is a wiring of the conductive layer 321 on the side of the component 103. A wiring 405 is a wiring of the conductive layer 321 on the side of the component 103, which is different from the land 300a. The land 300a of the conductive layer 321 on the side of the component 103 is insulated from the wiring 405 by the non-wired region 302.

FIG. 5E is a diagram illustrating disposition of conductive layers 323 and 322 on the side of the component 103. The small-diameter via 301 of the conductive layer 321 illustrated in FIG. 5D is connected to the small-diameter via 301 of the conductive layer 322 illustrated in FIG. 5E. Similarly, the small-diameter via 301 of the conductive layer 322 is connected to the small-diameter via 301 of the conductive layer 323. The land 301a is a wiring of the conductive layers 322 and 323 on the side of the component 103. A wiring 406 is a wiring of the conductive layers 322 and 323 on the side of the component 103, which is different from the land 301a. The land 301a of the conductive layers 322 and 323 on the side of the component 103 is insulated from the wiring 402 by the non-wired region 302.

FIG. 5F is a diagram illustrating disposition of the conductive layer 324 on the side of the component 103. The small-diameter via 301 of the conductive layer 323 illustrated in FIG. 5E is connected to the small-diameter via 301 of the conductive layer 324 illustrated in FIG. 5F and connected to the wiring 401. The wiring 401 and the land 301a are a wiring of the conductive layer 324 on the side of the component 103. The wiring 401 is connected to the component 103 via the solder 331. A wiring 407 is a wiring of the conductive layer 324 on the component 103, which is different from the wiring 401 and the land 301a. The wiring 401 and the land 301a is insulated from the wiring 407 by the non-wired region 302 where a conductor is not wired. The wirings 402 to 407 of the conductive layers described with reference to FIGS. 5(A) to 5(F) may not necessarily be the same node.

FIG. 5G is a diagram illustrating a state in which the conductors of the conductive layers are piled. When the conductive layers (see FIGS. 5(A) to 5(F)) of the multilayer substrate 102 are piled, non-wired regions 302a where there are no conductors in all the layers is formed in some cases. Since the vias (the drill via 300 and the small-diameter via 301) of the conductive layers are piled in a straight line, a region where the vias are also piled in all the layers is formed also in the non-wired regions 302 where there are no conductors provided around the vias, and the non-wired regions 302a where there are no conductors in all the layers are formed.

The non-wired region 302 includes a prepreg of an insulation layer and the solder resist 330. The prepreg is a material in which a resin is impregnated in fiber and does not have a light-shielding property. The solder resist 330 does not have a light-shielding property like the prepreg. That is, the non-wired region 302 formed with the prepreg and the solder resist 330 does not have a light-shielding property. Therefore, when the non-wired regions 302a where there are no conductors in all the layers are in a region corresponding to the image sensor 101 of the multilayer substrate 102, light transmitted through the multilayer substrate 102 may be incident on the image sensor 101 or the image sensor 101 may image light from the rear surface (the side of the multilayer substrate 102).

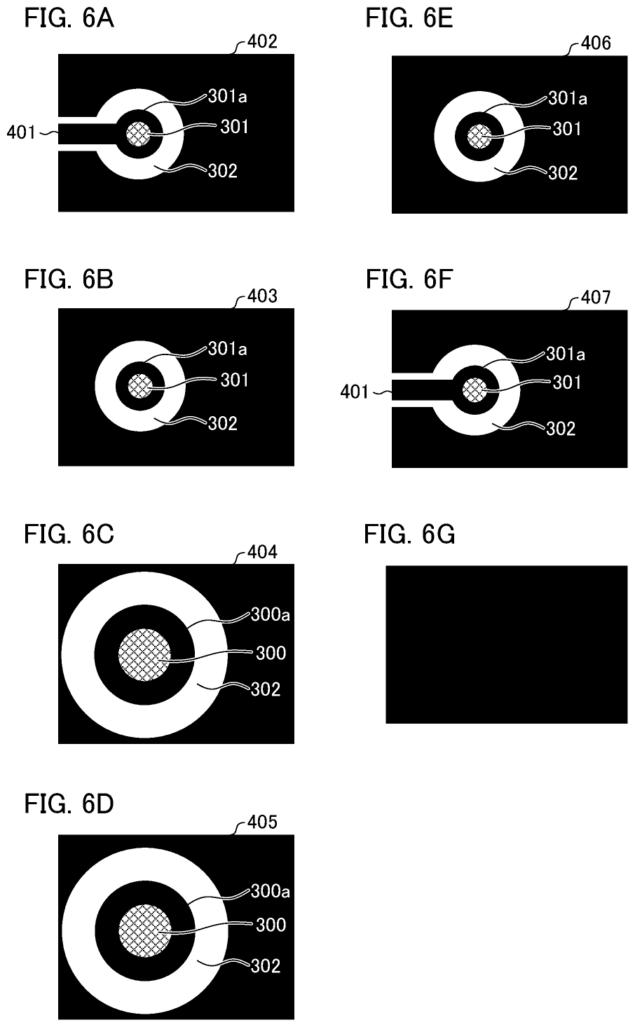

Accordingly, in the embodiment, by shielding light in the structure of the multilayer substrate 102, concern of the light incident on the image sensor 101 from the side of the multilayer substrate 102 being imaged is reduced. To shield light on the side of the multilayer substrate 102, for example, a light-shielding layer that shields light may be provided in the multilayer substrate 102 or the non-wired region 302 of each conductive layer which is a substance passing light may be disposed not to be piled. An example in which the non-wired region 302 of each conductive layer is disposed not to be piled will be described with reference to FIGS. 6A to 6G. FIGS. 6A to 6G are diagrams illustrating disposition of a wiring and a via of each conductive layer of the multilayer substrate 102 according to the embodiment.

FIG. 6A is a diagram illustrating disposition of the conductive layer 324 on the side of the image sensor 101. FIG. 6B is a diagram illustrating disposition of the conductive layers 323 and 322 on the side of the image sensor 101. FIG. 6A is similar to FIG. 5A and FIG. 6B is similar to FIG. 5B. Since the conductive layers 324, 323, and 322 on the side of the image sensor 101 according to the embodiment are configured similarly to the example of the related art, description thereof will be omitted. FIG. 6E is a diagram illustrating disposition of the conductive layers 323 and 322 on the side of the component 103. FIG. 6F is a diagram illustrating disposition of the conductive layer 324 on the side of the component 103. FIG. 6E is similar to FIG. 5E and FIG. 6F is similar to FIG. 5F. Since the conductive layers 322, 323, and 324 on the side of the component 103 according to the embodiment are configured similarly to the example of the related art, description thereof will be omitted.

FIG. 6C is a diagram illustrating disposition of the conductive layer 321 on the side of the image sensor 101. FIG. 6D is a diagram illustrating disposition of the conductive layer 321 on the side of the component 103. In the embodiment, the land 300a of the conductive layer 321 is disposed to be piled with the non-wired regions 302 of the other conductive layers (the conductive layers 322, 323, and 324) so that the non-wired regions 302 is not piled. Therefore, the land 300a of each conductive layer 321 according to the embodiment is formed in a pattern in a range broader than the non-wired regions 302 of the conductive layers 322, 323, and 324. The land 300a of the drill via 300 serves as a light-shielding portion that shields light transmitted through the multilayer substrate 102. Accordingly, light entered from the non-wired regions 302 of the conductive layers 322, 323, and 324 on the side of the component 103 can be shield by the land 300a of the conductive layer 321.

FIG. 6G is a diagram illustrating a state in which the conductors of the conductive layers are piled according to the embodiment. In the example of the related art, the non-wired regions 302a (see FIG. 5G) where there are no conductors in all the layers are formed. However, when the conductive layers (see FIGS. 6A to 6F) of the multilayer substrate 102 according to the embodiment are piled, it can be understood that a non-wired regions where there are no conductors in all the layers are not formed. In this way, by setting the structure of the multilayer substrate 102 in which the non-wired regions 302a where there are no conductors in all the layers are not formed, it is possible to shield light incident on the image sensor 101 from the multilayer substrate 102 in the multilayer substrate 102.

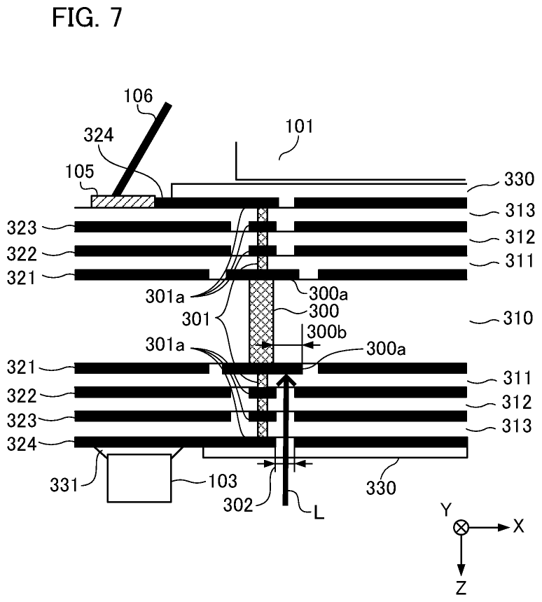

FIG. 7 is a diagram illustrating a structure of the multilayer substrate 102 according to the embodiment. The multilayer substrate 102 in FIG. 7 corresponds to the multilayer substrate 102 in FIGS. 6A to 6G. Hereinafter, differences from the multilayer substrate 102 of the related art illustrated in FIG. 4 will be described. The land 300a of the conductive layer 321 differs between the multilayer substrate 102 according to the embodiment and the multilayer substrate 102 of the related art. The land 300a according to the embodiment is formed in a pattern in a range broader than the land 300a of the related art in a substrate plane direction (XY plane direction). Specifically, the land 300a according to the embodiment is formed in a pattern in a range broader than the non-wired region 302 in the substrate plane direction so that the non-wired regions 302 of the other conductive layers (the conductive layers 322 to 324) are covered with the land 300a when viewed in an optical axis direction (the Z direction). Therefore, light (light beam L) transmitted through the non-wired regions 302 of the conductive layers 324 to 322 on the side of the component 103 is shielded by the land 300a of the conductive layer 321 on the side of the component 103.

When the non-wired regions 302 of all the conductive layers 321 to 324 are piled, light is transmitted through the multilayer substrate 102. Therefore, wirings (pattern) of some conductive layers may be piled with the non-wired regions 302 of the other conductive layers. In the embodiment, the example in which light is shielded by the land 300a of the conductive layer 321 has been described, but the present invention is not limited thereto. Light may be shielded by covering the non-wired regions 302 of the other conductive layers with the small-diameter via 301 or the wiring of the conductive layer other than the conductive layer 321.

The drill via 300 and the small-diameter via 301 according to the embodiment are, for example, high-speed transmission wirings, and a signal transmitted in the drill via 300 and the small-diameter via 301 is a high-speed transmission signal. The high-speed transmission wiring is, for example, a transmission path in which two signal lines are paired as one by adopting a transmission scheme for a low voltage differential signal (LVDS). Transmission of an imaging signal between the image sensor 101 and the multilayer substrate using the high-speed transmission wiring corresponds to high-speed transmission of the imaging signal. Since impedance of the high-speed transmission path is constantly managed, the non-wired region 302 is generally set to be greater than a wiring of a normal signal in the high-speed transmission path. In this way, since the non-wired region 302 is larger than a normal region in the high-speed transmission wiring, a region in which light can be transmitted than a normal signal is broadened. Therefore, the land 300a is formed in a pattern in a range 300b broader than the non-wired region 302 in the substrate plane direction to shield the light of the image sensor 101 so that the non-wired region 302 is covered with the land 300a of the drill via 300 which is a high-speed transmission wiring in the optical axis direction. In the embodiment, the example in which light is shielded by the land 300a of the conductive layer 321 has been described. However, the light beam L is prevented from being directly incident on the image sensor 101, which is applied to a via and a land in a lower surface region of the image sensor 101. In the embodiment, the example in which a high-speed transmission signal is transmitted in the drill via 300 and the small-diameter via 301 has been described, but the present invention is not limited thereto. The example may be applied to a normal signal or power.

In the embodiment, the multilayer substrate 102 has been described as the build-up substrate, but the multilayer substrate may be an any-layer substrate or the like. In the build-up substrate, the diameter of the drill via 300 which is the core layer via is larger than the diameter of the small-diameter via 301 which is an external layer via. In the any-layer substrate, however, the diameters of the drill via 300 and the small-diameter via 301 are the same. Therefore, in the any-layer substrate, without being limited to the land 300a of the drill via 300 in a core substrate, the land 301a of the small-diameter via 301 in the build-up layer may be formed in a pattern in a range broader than the non-wired region 302 to shield light from the rear surface of the image sensor 101.

A light-shielding portion capable of shielding light on the side of the multilayer substrate 102 may be provided not only inside the multilayer substrate 102 but also between the image sensor 101 and the multilayer substrate 102. Specifically, a light-shielding portion may be provided by printing a silk layer serving as a light-shielding layer on the front surface of the solder resist 330 on the image sensor side of the multilayer substrate 102. A light-shielding sheet serving as a light-shielding portion or a light-shielding layer such as an adhesive that has a light-shielding property may be provided on a surface on the side of the image sensor 101 between the image sensor 101 and the multilayer substrate 102. The solder resist 330 on the image sensor side may be black and the solder resist 330 itself may serve as a light-shielding portion that has a light-shielding property. The light shielding configurations may be combined.

As described above, according to the embodiment, by providing a light-shielding layer capable of shielding light inside the multilayer substrate 102 or between the image sensor 101 and the multilayer substrate 102, it is possible to shield light from the rear surface of the image sensor 101.

### Other Embodiments

The present invention can be implemented in a process in which a program implementing at least one function of the above-described embodiment can be supplied to a system or a device via a network or a storage medium and at least one processor in a computer of the system or the device reads and executes the program. The present invention can also be implemented by a circuit (for example, an ASIC) implementing at least one function.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. A multilayer substrate on which an image sensor is mounted and which includes a plurality of conductive layers, the multilayer substrate comprising:
a plurality of vias piled and connected in a straight line; and
a light-shielding portion configured to shield light transmitted through a non-wired region insulating the vias and other wirings and traveling to the image sensor.

2. The multilayer substrate according to claim 1, wherein the light-shielding portion is a land of the via formed in a range broader than the non-wired region of another conductive layer in at least one conductive layer.

3. The multilayer substrate according to claim 2, wherein the land is a land of a via of a core layer.

4. The multilayer substrate according to claim 1, wherein the multilayer substrate is an any-layer substrate.

5. The multilayer substrate according to claim 1, wherein the multilayer substrate is a build-up substrate.

6. The multilayer substrate according to claim 1, wherein the via is a high-speed transmission wiring.

7. The multilayer substrate according to claim 1, wherein the light-shielding portion is provided on a surface of a solder resist.

8. The multilayer substrate according to claim 7, wherein the light-shielding portion is one of a printed silk layer, a light-shielding sheet, and an adhesive with a light-shielding property.

9. The multilayer substrate according to claim 1, wherein the light-shielding portion is a black solder resist.

10. The multilayer substrate according to any one of claim 7, wherein the solder resist is a solder resist on an image sensor side.

11. An image sensor unit comprising:
a multilayer substrate including a plurality of conductive layers; and
an image sensor mounted on the multilayer substrate,
wherein the multilayer substrate comprising:
a plurality of vias piled and connected in a straight line; and
a light-shielding portion configured to shield light transmitted through a non-wired region insulating the vias and other wirings and traveling to the image sensor.
